(19) United States
(12) Patent Application Publication
(10) Pub. No.: US 2010/0300734 A1
(43) Pub. Date: Dec. 2, 2010

(54) Method and Apparatus for Building Multilayer Circuits

(75) Inventors: Billy D. Ables, Richardson, TX (US); Sankerlingam Rajendran, Plano, TX (US); Premjeet Chahal, Gurnee, IL (US)

Correspondence Address: BAKER BOTTS LLP, 2001 ROSS AVENUE, 6TH FLOOR, DALLAS, TX, 75201-2980, US

(73) Assignee: Raytheon Company, Waltham, MA (US)

(21) Appl. No.: 12/473,044

(22) Filed: May 27, 2009

(51) Int. Cl. H05K 1/09; B23K 31/02; H05K 1/00

(52) U.S. Cl. 174/257; 228/101; 174/250; 174/258

(57) ABSTRACT

An method for building multi-layer circuits without post process via fills is disclosed. The method includes aligning a first contact on a first substrate layer with a second contact on a second substrate layer; and fusion bonding the first contact to the second contact. A multilayer circuit is also disclosed. The multilayer circuit includes a first substrate layer including a first contact. The multilayer circuit also includes a second substrate layer including a second contact that is fusion bonded to the first contact such that the first and second contacts are aligned.

### TECHNICAL FIELD OF THE DISCLOSURE

This disclosure relates in general to semiconductor devices and more particularly, to building multilayer circuits

### BACKGROUND

Multilayer electronic circuits are built with a sequential build up of dielectric and metal layers. For instance, once a dielectric layer is formed, a conductor layer may be formed on top of the dielectric layer by depositing traces of conductive material in desired patterns on a surface of the dielectric. Additional layers may be added by sequentially attaching subsequent dielectric and metal layers to existing layers.

Forming electrical connections between dielectric and metal layers on the z-axis has included the need for plating vias after lamination to form electrical connections between layers or the need to cut holes in multilayer boards and fill the holes with solder to electrically connect layers in the z-axis. These methods require additional metallization and dielectric processing after layers are bonded. These additional steps make the formation of three-dimensional multilayer circuits more difficult.

### SUMMARY

A method for building multi-layer circuits is disclosed. The method includes aligning a first contact on a first substrate layer with a second contact on a second substrate layer. The method also includes fusion bonding the first contact to the second contact.

A multilayer circuit is also disclosed. The multilayer circuit includes a first substrate layer including a first contact. The multilayer circuit also includes a second substrate layer including a second contact that is fusion bonded to the first contact such that the first and second contacts are aligned.

Various embodiments of the present disclosure may benefit from numerous advantages. It should be noted that one or more embodiments may benefit from some, none, or all of the advantages discussed below. One advantage of certain embodiments is that z-axis connections between layers in a multilayer circuit may be formed without additional metallization or dielectric processes after dielectric layers are bonded. Another advantage of certain embodiments is that the multilayer circuit may be formed into three-dimensional structures without complications from metallization processes.

Other advantages will be readily apparent to one having ordinary skill in the art from the following FIGURES, descriptions, and claims.

### BRIEF DESCRIPTION OF THE DRAWINGS

For a more complete understanding of the present disclosure and for further features and advantages, reference is now made to the following description, taken in conjunction with the accompanying drawings, in which:

FIG. 1 illustrates a multilayer circuit according to one embodiment of the present disclosure.

FIG. 2A illustrates the surfaces of two substrate layers with traces before they are fusion bonded.

FIG. 2B illustrates a vertical view of a cross section of a multilayer circuit after the two surfaces shown in FIG. 2A are fusion bonded according to an embodiment of the present disclosure.

FIG. 3 illustrates a horizontal cross section of a multilayer circuit after the two surfaces shown in FIG. 2A are fusion bonded according to an embodiment of the present disclosure.

FIG. 4 illustrates a horizontal cross section of a multilayer circuit bent in the z-axis according to an embodiment of the present disclosure

FIG. 5A illustrates a horizontal cross section of a multilayer circuit and an electronic device suspended above the multilayer circuit.

FIG. 5B illustrates a horizontal cross section of a multilayer circuit with an electronic device fusion bonded in the multilayer circuit according to an embodiment of the present disclosure.

FIG. 6A illustrates a horizontal cross section of a multilayer circuit and an integrated circuit package suspended above the multilayer circuit.

FIG. 6B illustrates a horizontal cross section of a multilayer circuit with an integrated circuit package fusion bonded in the multilayer circuit according to an embodiment of the present disclosure.

### DETAILED DESCRIPTION OF THE DRAWINGS

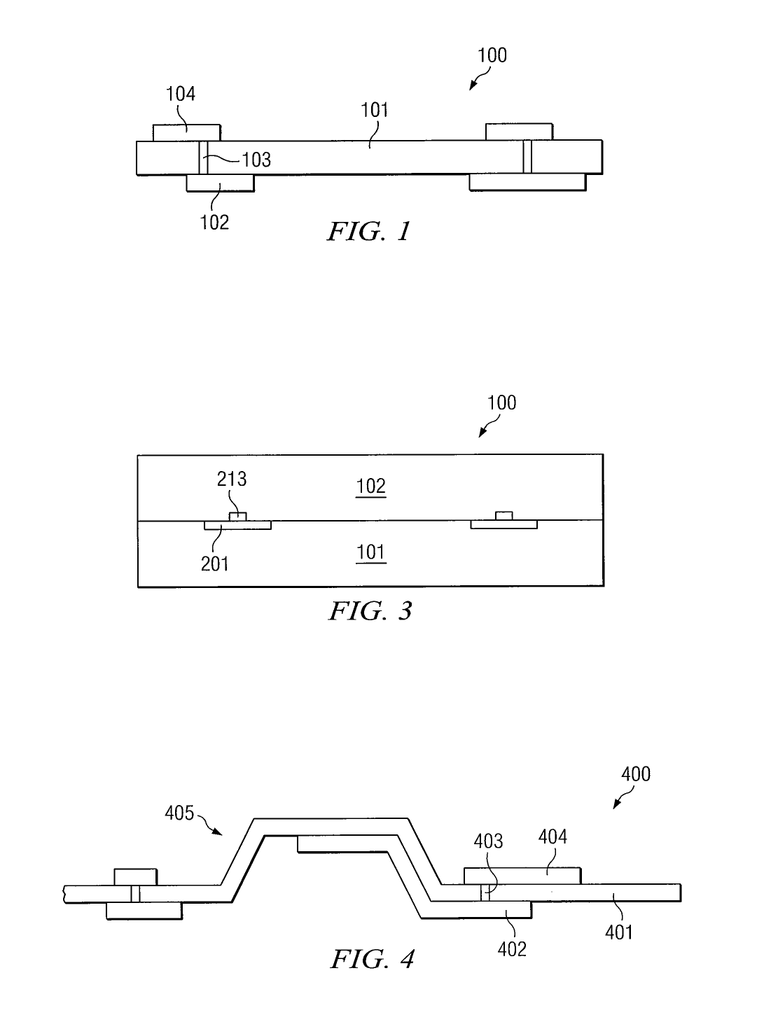

Example embodiments of the present disclosure and their advantages are best understood by referring now to FIGS. 1-6 of the drawings in which like numerals refer to like parts.

According to some embodiments of the present disclosure, a fusion bonding procedure that forms a conductor to conductor, or metal to metal connection or electrical path without the use of a solder joint, wire bond, or ribbon bond can be used to create circuits between multiple layers of a printed circuit board. A procedure for using a fusion bonding method to create these circuit connections between multiple layers of a printed circuit board is disclosed. Liquid crystal polymers (LCPs) having coefficients of thermal expansion close to one another are chosen. These LCPs have interconnect traces or contact patterns on their surfaces such that desired circuits or microelectronic component connections can be made. For instance, it may be desirable to connect an electronic component on one LCP or substrate layer to another electronic component on a different substrate or LCP layer.

According to some embodiments of the present disclosure, traces or contacts are deposited on the surface of the first substrate layer that may connect to an electronic component on the first layer. Traces or contacts are also deposited on the surface of the second substrate layer that may connect to a component on the second layer. These traces or contacts can be made of any conductive material, such as copper, gold, silver, platinum, or aluminum. The traces are made such that they align at desirable connection points when the surfaces of the two substrates are placed together. Once contacts are aligned and substrates are placed together, the two substrates are subjected to standard autoclave procedures such that the substrate layers are fusion bonded, as well as the metal contacts. For instance, the aligned substrate and LCP are placed in an autoclave and processed at the appropriate temperature and pressure to bond the LCP surfaces and to capture the contacts and interconnects such that the contacts and interconnects between the LCP and the substrate bond. For example, pressures between 50 and 100 PSI and temperatures between 200 and 290 degrees Celsius may be used to bond the contacts and substrate surfaces.

LCPs having coefficients of thermal expansion close to one another may be chosen so that the contacts remain aligned during any expansion by the substrates. In this way, multiple layers of LCPs and/or substrates can be bonded together while at the same time contacts or traces on one layer and contacts or traces on another layer can also be bonded creating circuits and connections that traverse the Z-axis between layers in addition to the X and Y axis within an individual layer. This fusion bonding technique can be used to create and/or connect multilayer circuits, antenna structures, resonators, cooling channels, microprocessors, or any of a number of electronic components known in the art.

In reference to FIG. 1, FIG. 1 shows a horizontal section of multilayer circuit 100. The center layer is a liquid crystal polymer layer 101. Layer 101 is connected to a bottom layer 102 and a top layer 104. A metal contact 103 is shown that traverses the width of layer 101 and connects layers 102 to layer 101 and layer 101 to layer 104. The embodiment of FIG. 1 shows a printed circuit board where multiple layers are bonded together using fusion bonding and wherein circuit connections are created between substrate layers 101, 102 and 104 by bonding traces together using fusion bonding.

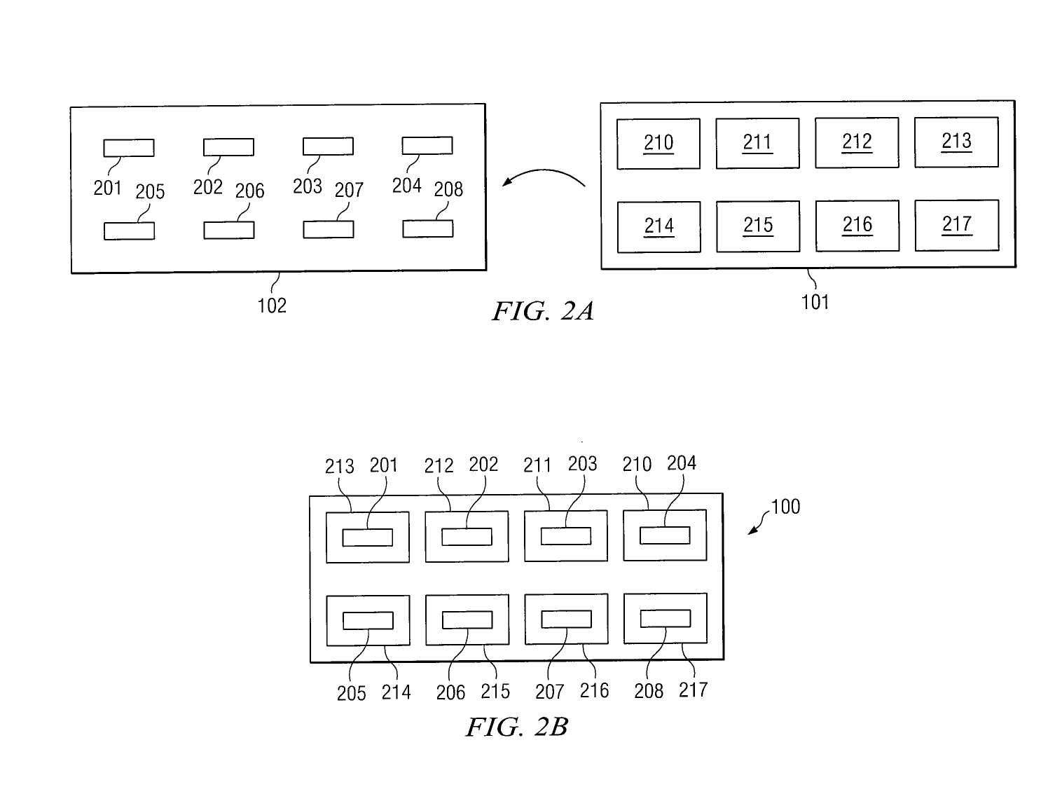

In reference to FIG. 2, FIG. 2A shows two substrate layers or LCP layers identified as 102 on the left hand side and 101 on the right hand side. This view shows layers 101 and 102 from FIG. 1 before the layers are fusion bonded. Layer 102 has a series of conductor traces or connections or contacts identified as 201, 202, 203, 204, 205, 206, 207 and 208. These conductor traces or connections are printed on a top surface of substrate layer 102 using known conductor depositing methods. These interconnects may be connected to microcontrollers or any other electronic device component. They may form circuits by themselves or they may further connect to other layers beneath layer 102 that form other circuits. Layer 101 also has a series of conductor connections or traces or contacts printed on its bottom surface. These contacts are identified as 210, 211, 212, 213, 214, 215, 216 and 217.

According to an embodiment of the present disclosure, the top surface of layer 102 is aligned with the bottom surface of layer 101 such that the interconnects are aligned together. For example, interconnect 201 on layer 102 aligns to interconnect 213 and layer 101. In essence the bottom surface of layer 101 as shown on the right hand side of FIG. 2A is placed on top of the top surface of layer 102 as shown in the left hand side of FIG. 2A such that the metal traces are aligned with one another and are in contact. Once layers 102 and 101 are properly aligned and placed on top of one another, they are autoclaved in a standard autoclave such that the LCP layers are fusion bonded and also such that the metal or nonmetal contacts and interconnects are fusion bonded. The bonded layers are shown in FIG. 2B on multilayer circuit 100. FIG. 2B shows a vertical cross section view of interconnect 213 from layer 101 and interconnect 201 from layer 102 bonded together. In some embodiments, the LCP or substrate layers 102 and 101 are chosen such that the coefficients of thermal expansion for each layer (CTE) matches one another such that the pressure and temperature they are subjected to in the autoclave procedure creates the same level of expansion and the alignment throughout the process of fusion bonding is maintained. It should be noted that the interconnects on 102 and 101 can be predetermined interconnect patterns to create a desired circuit or electronic component connection.

In reference to FIG. 3, FIG. 3 shows a horizontal cross section of circuit 100 and LCP layers 101 and 102 after they are bonded using the fusion bonding process. FIG. 3 shows interconnect 213 connected to interconnect 201. Prior to the fusion bonding, interconnect 201 was connected to the bottom surface of layer 102 and interconnect 213 was connected to the top layer of layer 101. Once subject to the appropriate temperature and pressure and after the two layers 101 and 102 are properly aligned, connections 201 and 213 are bonded forming a Z-axis connection between layers 101 and 102.

In reference to FIG. 4, FIG. 4 shows a three-dimensional multilayer circuit structure created using the fusion bonding technique discussed with respect to FIGS. 1-3. FIG. 4 shows printed circuit board or multilayer circuit 400. Multilayer circuit 400 includes layer 402 bonded to layer 401 and layer 404 bonded to layer 401. Layer 401 has a metal interconnect 403 traversing its width. Interconnect 403 is connected to an interconnect (not shown) on layer 402 where they interface and to an interconnect (not shown) on layer 404 where they interface. In this way, circuits formed on layer 402 can be connected to circuits on layers 401 and circuits on layers 404 allowing Z-axis connections through the circuit board. Using the fusion bonding method of the present disclosure, multilayer circuit 400 can be formed using the fusion bonding method previously discussed and then placed in molds and subjected to temperatures and pressures known in the art to allow the formation of the 3-D structure shown in 400. The molding can take place without the need for post lamination via fills or contact plating to create connections between layers. Furthermore, the circuit shown in FIG. 4 can be formed with one autoclave procedure by properly aligning the components using known techniques. This single bonding procedure removes many processing steps.

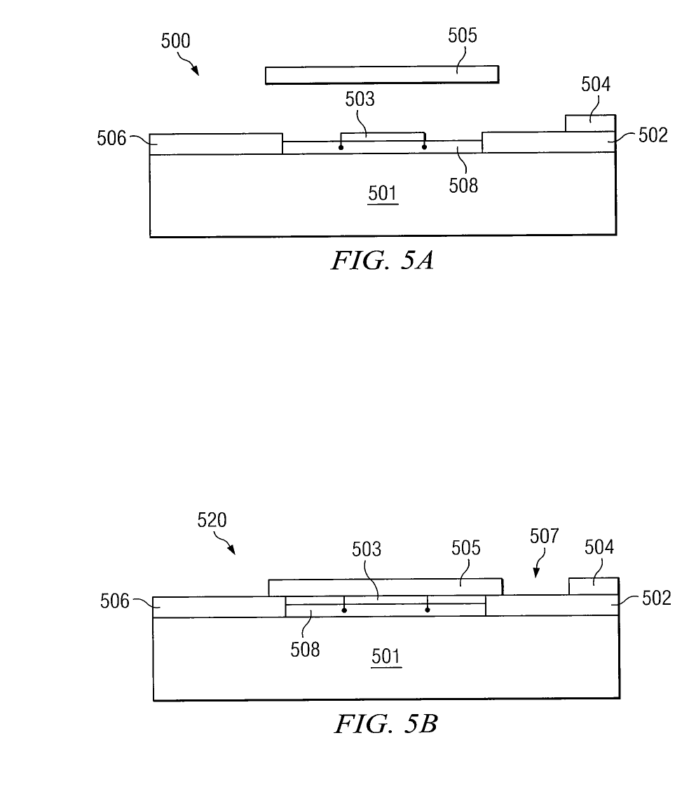

In reference to FIG. 5A, FIG. 5A shows an embodiment where fusion bonding is used to embed a chip within a dielectric layer or chip packaging. The metal connections on the bottom and/or top of embedded chip 503 are formed during the lamination step or during the processing step of chip 503. Chip 503 has been fusion bonded to surface or dielectric layer 508. FIG. 5A shows a configuration where it may be desirable to connect embedded chip 503 to both layer 508 and to layer 505. FIG. 5A shows layer 505 above chip 503. According to some embodiments, layer 505 has traces on its bottom surface. These traces are aligned to the traces on the top surface of embedded chip 503, similar to what is illustrated with respect to FIGS. 2 and 2A. Layer 505 is then placed on top of layer 503 such that the contacts on the bottom surface of 505 and 503 are aligned. They are placed in the standard autoclave procedures such that the interconnect and trace layers on 505 and 503 are bonded, as shown in FIG. 5B. In this way embedded chip 503 is connected to the traces for connections on both layers 508 and layers 505. Layer 505 is also bonded to layers 506 and 502.

FIG. 5B also shows a gap 507 between layers 505 and 504. This gap can subsequently be filled with another layer of conductor or trace or conduction material such that a additional layers can be built on top of space 507 create yet another Z-axis circuit connection. As discussed, FIG. 5A shows configuration 500 prior to layer 505 being bonded to layers 503, 506 and 502. FIG. 5B shows multilayer circuit 520, which is the combined multilayer circuit after fusion bonding has been applied.

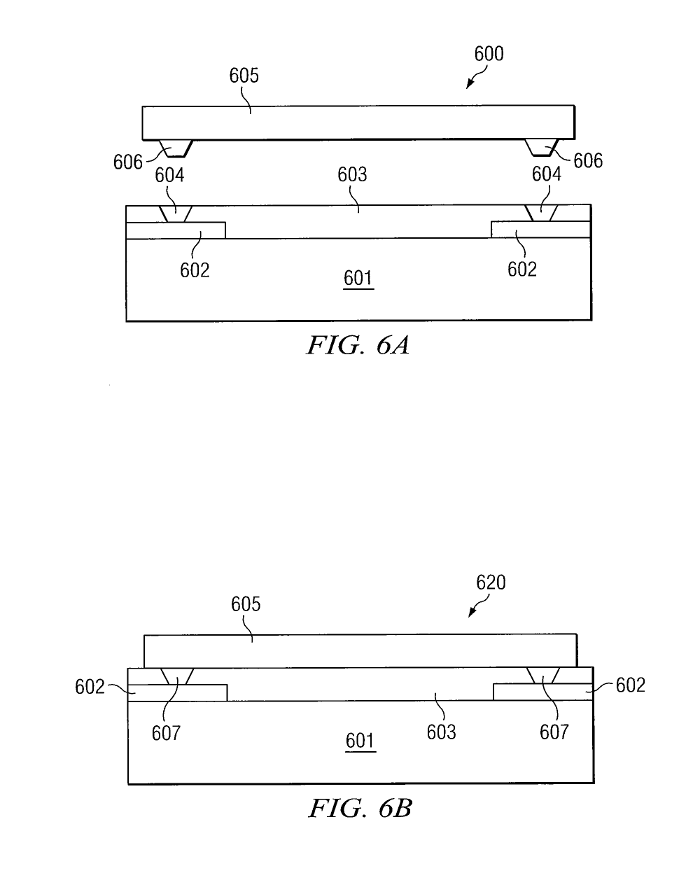

In reference to FIG. 6A, FIG. 6A shows a configuration 600 comprising substrate layer 601 and chip package 605. Layer 601 has an additional substrate layer 603 and traces 602 and interconnect 604 connected to trace 602. Shown above substrate layer 601 is a microchip package 605. 605 can be any microchip or electronic component that includes contacts or traces 606 on its bottom surface. Using the fusion bonding technique of the present disclosure, contacts 606 on chip 605 are aligned with traces or contacts 604 on layer 601. Once they are aligned, the contacts are put into contact and placed a autoclave procedure such that contact 606 becomes bonded with contact 604. This is shown in FIG. 6B. Configuration 620 shows a bonded microchip 605 connected at the bonded contact or trace 607, which is subsequently connected to trace 602 on the overall layer 601. In this way chips may be attached to printed circuit boards or to LCP or substrate layers using the fusion bonding method.

Although an embodiment of the disclosure and its advantages are described in detail, a person skilled in the art could make various alterations, additions, and omissions without departing from the spirit and scope of the present disclosure as defined by the appended claims.

What is claimed is:

1. A method for connecting contacts comprising:
aligning a first contact on a first substrate layer with a second contact on a second substrate layer; and
fusion bonding the first contact on the first substrate layer to the second contact on the second substrate layer.

2. The method of claim 1 wherein the first and second substrate layers have the same coefficient of thermal expansion.

3. The method of claim 1 wherein the substrate layers comprise liquid crystal polymer.

4. The method of claim 1 wherein the first contact and second contact each comprise a material selected from the group consisting of gold, copper, silver, aluminum, and platinum.

5. The method of claim 1 further comprising connecting the first contact to the second contact without plating the contacts.

6. The method of claim 1 wherein the bonded first contact and second contact form a member selected from the group consisting of circuits, antennas, resonators, cooling channels, and chip packages.

7. The method of claim 1 further comprising placing the combined substrate layers in a mold to form a shape.

8. A multilayer circuit comprising:
a first substrate layer comprising a first contact;
a second substrate layer comprising a second contact fusion bonded to the first contact of the first substrate layer such that the first and second contacts are aligned.

9. The multilayer circuit of claim 8 wherein the first and second substrate layers have the same coefficient of thermal expansion.

10. The multilayer circuit of claim 8 wherein the substrate layers comprise liquid crystal polymer.

11. The multilayer circuit of claim 8 wherein the first contact and second contact each comprise a material selected from the group consisting of gold, copper, silver, aluminum, and platinum.

12. The multilayer circuit of claim 8 wherein the fusion bonded first and second contact are not plated.

13. The multilayer circuit of claim 8 wherein the bonded first contact and second contact form a member selected from the group consisting of circuits, antennas, resonators, cooling channels, chip packages.

14. The multilayer circuit of claim 8 wherein the multilayer circuit is bent along the z-axis.

15. A method for building a multi-layer circuit comprising:
aligning a first contact on a first substrate layer with a second contact on a second substrate layer wherein each substrate layer has a length, width, and thickness, and wherein the first and second contacts are on surfaces defined by each substrate's length and width; and
creating a multi-layer circuit by fusion bonding the first contact on the first substrate to the second contact on the second substrate by applying pressure and heat to the first and second substrate layers.

16. The method of claim 15 wherein the first and second substrate layers have the same coefficient of thermal expansion.

17. The method of claim 15 wherein the first contact and second contact each comprise a material selected from the group consisting of gold, copper, silver, aluminum, and platinum.

18. The method of claim 15 further comprising creating a multi-layer circuit by fusing the first and second contacts without plating the contacts.

19. The method of claim 15 wherein the bonded first contact and second contact form a member selected from the group consisting of circuits, antennas, resonators, cooling channels, chip package.

20. The method of claim 15 further comprising placing the combined substrate layers in a mold to form a shape.
